(19) United States
(12) Patent Application Publication
(10) Pub. No.: US 2018/0166367 A1
(43) Pub. Date: Jun. 14, 2018

(54) FLIP-CHIP PACKAGING DIODE WITH A MULTICHIP STRUCTURE

(71) Applicant: FORMOSA MICROSEMI CO., LTD., New Taipei City (TW)

(72) Inventors: Wen-Hu WU, New Taipei City (TW); Chien-Wu CHEN, New Taipei City (TW); His-Piao LAI, New Taipei City (TW); Hui-Min LIN, New Taipei City (TW)

(73) Assignee: FORMOSA MICROSEMI CO., LTD., New Taipei City (TW)

(21) Appl. No.: 15/399,797

(22) Filed: Jan. 6, 2017

(30) Foreign Application Priority Data
Dec. 9, 2016 (TW) 105140864

(51) Int. Cl. H01L 23/495; H01L 23/31; H01L 23/00

(52) U.S. Cl. CPC H01L 23/49575; H01L 23/49537; H01L 23/49524; H01L 29/861; H01L 23/3185; H01L 24/05; H01L 23/49562

(57) ABSTRACT

A flip-chip packaging diode with a multichip structure includes at least two flip-chips arranged with an interval apart from each other and horizontally disposed on the top of a lower guide plate, and each flip-chip has a bottom electrically connected to the lower guide plate and a top having a conductive layer. An insulating material is filled between the two flip-chips and at the outer periphery of the two flip-chips, so that the conductive layers at the tops of the two flip-chips are isolated to form a first electrode and a second electrode for electrically connecting an external circuit. With this structure, a series circuit is formed between the two flip-chips.

### FIELD OF INVENTION

The present invention relates to a flip-chip packaging diode with a multichip structure, in particular to a diode having at least two flip-chips installed horizontally on the top of a lower guide plate and with an interval apart from each other, and a series circuit formed between the at least two flip-chips, so that the diode has a voltage resistance characteristic which is applicable for the flip-chip packaging of a general rectification/protection diode, and particularly for the flip-chip packaging of a high-voltage diode.

### BACKGROUND OF INVENTION

### 1. Description of the Related Art

With reference to FIG. 1 for a conventional packaging technology of a surface mount device (SMD) diode, positive and negative electrodes of a single chip 100 are connected to two electrode pins 101 respectively by wire bonding or soldering, and then an insulator 102 is wrapped around the exterior of the SMD diode, so that two electrode pins 101 are partially exposed from the insulator 102 to form the SMD diode.

In FIG. 1, both positive and negative electrodes of the single chip are soldered to the electrode pins respectively, and the insulator used for wrapping the SMD diode, so that the total volume is relatively large. In addition, the two electrode pins 101 used in the manufacturing process are generally in form of a plate (not shown in the figure) which is formed by stamping and bending upwardly, and cutting the plate after the packaging is completed. Obviously, the manufacturing process is complicated, and such process is a prior art, and thus will not be described here.

In the SMD diodes manufactured by the conventional packaging technology, if a rectification/protection circuit or any circuit requiring a high-voltage resistance is used, more diodes are installed to the circuit to increase the voltage, and there is another alternative of improving the voltage resistance characteristic of each diode. However, the improvement is very limited.

In FIG. 2, a well-known method of improving the voltage resistance of a single SMD diode is to electrically connect upper and lower stacks of two chips 100, and then one of the electrode pins 101 is soldered to the top of the upper chip, and the other electrode pin 101 is electrically soldered to the bottom of the lower chip, so that the two upper and lower stacked chips 100 form a series circuit, and then an insulator is wrapped around the exterior of the SMD diode.

In the aforementioned single SMD diode, the series circuit formed by the upper and lower stacked chips 100 is provided for improving the voltage resistance characteristic, so as to enhance the voltage resistance characteristic significantly. However, the figure clearly shows that the upper and lower stacked chips 100 increase the total height of the diode, and the increased height (or thickness) is not conducive to the height (or thickness) requirement of the circuit board of 3C products. In addition, it is necessary to bend the upper electrode pin 101 to a larger angle and extend it to a farther distance before it can be soldered to the top of the upper chip.

Since the two electrode pins are formed by stamping and bending a plate material, therefore the bending angle and length of extension cause tremendous limitation and inconvenience in the manufacturing process, and that is why most conventional way of packaging diodes at most use two chips, and any manufacturing process exceeding two chips will be very difficult.

In order to reduce the volume of the diode, the flip-chip packaging technology becomes a very important milestone for the development of packaging the SMD diodes. The so-called “flip-chip” is to form a bump at a chip connecting point during the manufacturing process, and then the chip is flipped such that the bump is directly connected to a lower guide plate (or a substrate). Unlike the conventional chip packaging as shown in FIG. 1, the two electrodes of the chip are electrically coupled to the electrode pins respectively by soldering or wire bonding.

In FIG. 3, the flip-chip packaging technology is used to produce a diode, wherein two electrodes 202 are installed in open ditches 201 formed on the same side of the chip 200 without the need of using additional plate materials and electrode pints to electrically connect the external circuit, and such arrangement not just simplify the manufacturing process significantly only, but also making the chip core of the diode to have a scale very close to the packaged scale. Therefore, such package is called chip scale package (CSP) capable of reducing the volume of the diode. Since the conventional flip-chip packaging technologies involve the single-chip structure, these technologies have the drawbacks of unable to make use of a small flip-chip to manufacture high-power high-voltage diodes or polycrystalline layered diodes.

In view of the advantages of the flip-chip packaging technology, the inventor of the present invention made use of the flip-chip packaging technology to overcome the aforementioned drawbacks of the conventional SMD diodes including the size limitation and the limited CSP voltage resistance characteristic and developed a flip-chip packaging diode with a multichip structure in accordance with the present invention.

### SUMMARY OF THE INVENTION

Therefore, it is a primary objective of the present invention to overcome the drawbacks of the prior art and provide a flip-chip packaging diode with a multichip structure not just capable of reducing the size of the conventional diodes only, but also capable of conveniently increasing the quantity of flip-chips depending on the voltage resistance requirement and fitting the flip-chip packaging of general rectification/protection diodes, and particularly the flip-chip packaging of high-voltage diodes.

To achieve the aforementioned and other objectives, the present invention discloses a flip-chip packaging diode with a multichip structure comprising at least one first flip-chip and a second flip-chip arranged with an interval apart from one another and horizontally disposed at the top of a lower guide plate, characterized in that the bottom of the first flip-chip and the bottom of the second flip-chip are electrically coupled to the lower guide plate, and each of the top of the first flip-chip and the top of the second flip-chip has a conductive layer; an insulating material is filled between the first flip-chip and the second flip-chip and the outer periphery of the first flip-chip and the outer periphery of the second flip-chips, so that the conductive layers at the top of the first flip-chip and the top of the second flip-chips are separated from each other; a tin platform or a metal layer is disposed on the conductive layers at the top of the first flip-chip and the top of the second flip-chip and exposed from the insulating material to serve as a first electrode and a second electrode respectively for electrically coupling an external circuit; and an electrical transmission path sequentially passing from the first electrode through the first flip-chip, the lower guide plate, and the second flip-chip to the second electrode forms a series circuit.

Wherein, the first flip-chip and the second flip-chip are unidirectionally conducted unidirectional flip-chips, and the bottom of the first flip-chip and the bottom of the second flip-chip are arranged in different polar directions.

In a preferred embodiment of the unidirectional flip-chip, each of the bottom of the first flip-chip and the bottom of the second flip-chip has a vertical and downward laminate flip-chip, or a plurality of vertical and downward laminate flip-chips arranged in different polar directions at their adjacent electrical connection surfaces, characterized in that the two laminate flip-chips disposed at the bottom of the first flip-chip and the bottom of the second flip-chip are arranged in different polar directions at the electrical connection surface between the first flip-chip and the second flip-chip, and the bottoms of the two laminate flip disposed on the top of the lower guide plate are arranged in different polar directions and electrically coupled to the lower guide plate; and an electrical transmission path sequentially passing from the first electrode through the first flip-chip, the one or more laminate flip-chips, the lower guide plate, the one or more laminate flip-chips, and the second flip-chip to the second electrode forms a series circuit.

In a preferred embodiment of the unidirectional flip-chip, the first flip-chip and the second flip-chip have a third flip-chip and a fourth flip-chip horizontally disposed with an interval apart from each other, and the lower guide plate is cut and separated into a first lower guide plate and a second lower guide plate, characterized in that the third flip-chip and the first flip-chip are arranged in different polar directions with respect to each other, and the bottom of the third flip-chip and the bottom of the first flip-chip are electrically coupled to the first lower guide plate; the fourth flip-chip and the second flip-chip are arranged in different polar directions with respect to each other, and the fourth flip-chip and the second flip-chip bottom are electrically coupled to the second lower guide plate; the third flip-chip and the fourth flip-chip are arranged in different polar directions with respect to each other, and an upper guide plate is bridged between the top of the third flip-chip and the top of the fourth flip-chip; and an electrical transmission path sequentially passing from the first electrode through the first flip-chip, the first lower guide plate, the third flip-chip, the upper guide plate, the fourth flip-chip, the second lower guide plate, and the second flip-chip to the second electrode forms a series circuit.

Wherein, the first flip-chip, the second flip-chip, the third flip-chip and the fourth flip-chip come with a plural quantity and are vertically stacked with respect to one another, and the plurality of stacked first flip-chips, second flip-chips, third flip-chips and fourth flip-chips are arranged in different polar directions at their adjacent electrical connection surfaces; wherein the first lower guide plate is electrically coupled to the bottom-layer third flip-chip and the bottom-layer first flip-chip bottom, and the second lower guide plate is electrically coupled to the bottom-layer fourth flip-chip and the bottom-layer second flip-chip bottom, and the upper guide plate is bridged between the top of the top-layer third flip-chip and the top of the top-layer fourth flip-chip.

Wherein, the first flip-chip and the second flip-chip are bidirectionally conducted bidirectional flip-chips, and the bottom of the first flip-chip and the bottom of the second flip-chip are arranged in the same polar direction.

In a preferred embodiment of the bidirectional flip-chip, each of the bottom of the first flip-chip and the bottom of the second flip-chip has a vertical and downward laminate flip-chip, or a plurality of vertical and downward laminate flip-chips arranged in the same polar direction at their adjacent electrical connection surfaces, characterized in that the two laminate flip-chips disposed at the bottom of the first flip-chip and the bottom of the second flip-chip are in arranged the same polar direction at the electrical connection surface between the first flip-chip and the second flip-chip, and the bottoms of the two laminate flip-chips disposed on the top of the lower guide plate are arranged in the same polar direction and electrically coupled to the lower guide plate; and an electrical transmission path sequentially passing from the first electrode through the first flip-chip, the one or more laminate flip-chips, the lower guide plate, the one or more laminate flip-chips, and the second flip-chip to the second electrode forms a series circuit, and an electrical transmission path in the reverse direction is also a series circuit.

In a preferred embodiment of the bidirectional flip-chip, the first flip-chip and the second flip-chip have a third flip-chip and a fourth flip-chip arranged parallel to each other and with an interval apart from each other, and the lower guide plate is cut and separated into a first lower guide plate and a second lower guide plate, characterized in that the third flip-chip and the first flip-chip are arranged in the same polar direction, and the bottom of the third flip-chip and the bottom of the first flip-chip are electrically coupled to the first lower guide plate; the fourth flip-chip and the second flip-chip are arranged in the same polar direction, and the bottom of the fourth flip-chip and the bottom of the second flip-chip are electrically coupled to the second lower guide plate; the third flip-chip and the fourth flip-chip are arranged in the same polar direction, and an upper guide plate is bridged between the top of the third flip-chip and the top of the fourth flip-chip; and an electrical transmission path sequentially passing from the first electrode through the first flip-chip, the first lower guide plate, the third flip-chip, the upper guide plate, the fourth flip-chip, the second lower guide plate, and the second flip-chip to the second electrode forms a series circuit, and an electrical transmission path in the reverse direction is also a series circuit.

Wherein, the first flip-chip, the second flip-chip, the third flip-chip and the fourth flip-chip come with a plural quantity and are vertically stacked with respect to one another, and the plurality of stacked first flip-chips, second flip-chips, third flip-chips and fourth flip-chips are arranged in the same polar direction at their adjacent electrical connection surfaces; wherein the first lower guide plate is electrically coupled to the bottom of the bottom-layer third flip-chip and the bottom of the bottom-layer first flip-chip; the second lower guide plate is electrically coupled to the bottom of the bottom-layer fourth flip-chip and the bottom of the bottom-layer second flip-chip, and the upper guide plate is bridged between the top of the top-layer third flip-chip and the top of the top-layer fourth flip-chip.

Compared with the conventional packaging method which is capable of vertically stacking and connecting at most two chips in series, the flip-chip packaging diode of the present invention not just increases the voltage resistance significantly in the condition of the same height only, but also conveniently and unlimitedly increases the quantity of flip-chips depending on the voltage resistance requirement, which is applicable for the flip-chip packaging of general rectification/protection diodes, and particularly for the flip-chip packaging of high-voltage diodes.

### BRIEF DESCRIPTION OF THE DRAWINGS

FIG. 1 is a schematic view of a SMD diode with a conventional packaging structure;

FIG. 2 is a schematic view of a conventional structure of a SMD diode having two chips installed therein;

FIG. 3 is a schematic view of a SMD diode with a conventional flip-chip packaging structure;

FIG. 4 is a schematic view of a unidirectional flip-chip structure in accordance with a first preferred embodiment of the present invention;

FIG. 5 is a schematic view of a unidirectional flip-chip having a multiple of vertically stacked flip-chips in accordance with the present invention;

FIG. 6 is a schematic view of a unidirectional flip-chip having a multiple of horizontally stacked flip-chips in accordance with the present invention;

FIG. 7 is a schematic view of a unidirectional flip-chip having a multiple of horizontally and vertically stacked flip-chips in accordance with the present invention;

FIG. 8 is a schematic view of a bidirectional flip-chip structure in accordance with a second preferred embodiment of the present invention;

FIG. 9 is a schematic view of a bidirectional flip-chip having a multiple of vertically stacked flip-chips in accordance with the present invention;

FIG. 10 is a schematic view of a bidirectional flip-chip having a multiple horizontally stacked flip-chips in accordance with the present invention;

FIG. 11 is a schematic view of a bidirectional flip-chip having a multiple of horizontally and vertically stacked flip-chips in accordance with the present invention; and

FIG. 12 is a top view of an arrangement of a multiple of horizontally installed flip-chips in accordance with the present invention.

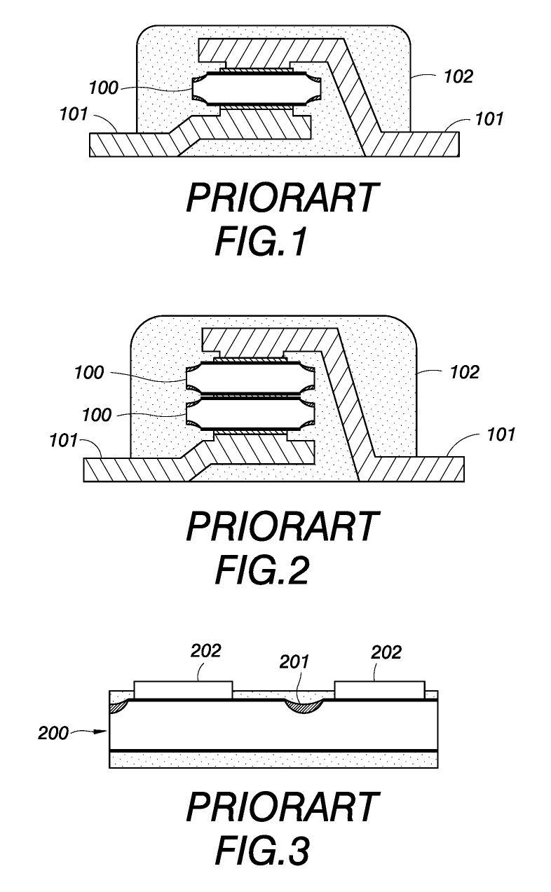

### DESCRIPTION OF THE PREFERRED EMBODIMENTS

The above and other objects, features and advantages of this disclosure will become apparent from the following detailed description taken with the accompanying drawings.

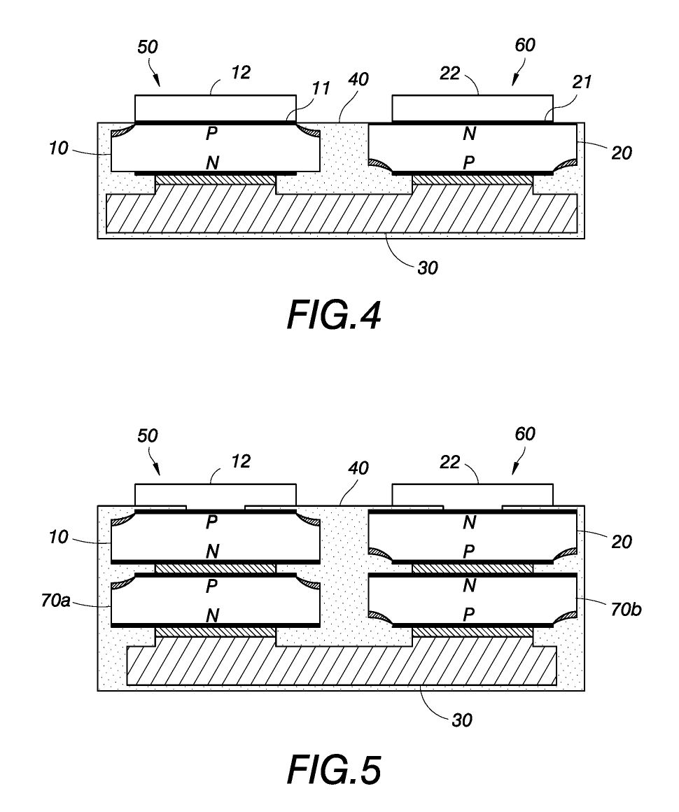

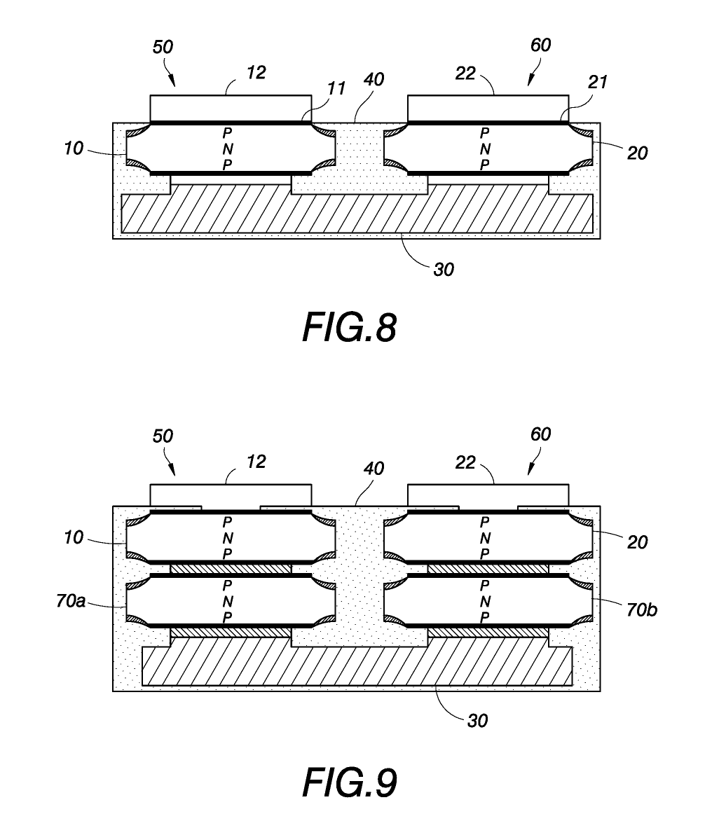

With reference to FIGS. 4 and 8 for a flip-chip packaging diode with a multichip structure of the present invention, the flip-chip packaging diode with a multichip structure comprises at least one first flip-chip 10 and a second flip-chip 20 installed at the top of a lower guide plate 30, and the first flip-chip 10 and the second flip-chip 20 are arranged horizontally and with an interval apart from each other. Wherein, the bottom of the first flip-chip 10 and the bottom of the second flip-chip 20 are electrically coupled to the lower guide plate 30, and each of the tops of the first and second flip-chips 10, 20 has a conductive layer 11, 21, and an insulating material 40 is filled between the first flip-chip 10 and the second flip-chip 20 and at the outer periphery of the first and second flip-chips 10, 20, so that the conductive layers 11, 21 at the top of the first flip-chip 10 and the top of the second flip-chip 20 are separated with each other. In the figures, each of the conductive layers 11, 21 of the first flip-chip 10 and the second flip-chip 20 has a tin platform or a metal layer 12, 22 exposed from the insulating material 40 to serve as a first electrode 50 and a second electrode 60 for electrically connecting an external circuit.

During the use of the aforementioned diode, the first electrode 50 and the second electrode 60 are coupled to the positive and negative electrodes of the external circuit, and an electrical transmission path passing from the first electrode 50 through the first flip-chip 10, the lower guide plate 30, and the second flip-chip 20 to the second electrode 60 forms a series circuit, wherein the first flip-chip 10 and the second flip-chip 20 are connected in series to improve the electrical characteristic of the voltage resistance without increasing the total height of the diode. Compared with the conventional packaging process, the present invention is much more convenient and applicable for the flip-chip packaging of general rectification/protection diodes, and particularly for the flip-chip packaging of high-voltage diodes.

In FIG. 4, the first flip-chip 10 and the second flip-chip 20 are unidirectionally conducted unidirectional flip-chips, and the bottom of the first flip-chip 10 and the bottom of the second flip-chip 20 are arranged in different polar directions (such as positive electrode P and negative electrode N) and electrically coupled to the lower guide plate 30, so that the first electrode 50 and the second electrode 60 are in different polar directions. Unlike FIG. 4, FIG. 4 discloses a first flip-chip 10 and a second flip-chip 20 which area bidirectionally conducted bidirectional flip-chips, and the bottom of the first flip-chip 10 and the bottom of the second flip-chip 20 are arranged in the same polar direction and electrically coupled to the lower guide plate 30, so that the first electrode 50 and the second electrode 60 are in the same polar direction (both are positive electrodes P).

In the aforementioned structure, the flip-chip is not limited by the conventional plate material, so that the present invention may increase the quantity of flip-chips conveniently. In the preferred embodiment of the unidirectional flip-chip as shown in FIG. 5, one or more laminate flip-chips may be stacked vertically at the bottom of the first flip-chip 10 and the bottom of the second flip-chip 20 to increase the quantity of flip-chips. For example, one laminate flip-chip 70a, 70b is installed to each of the bottom of the first flip-chip 10 and the bottom of the second flip-chip 20 as shown in the figure.

Wherein, the two laminate flip-chip 70a, 70b disposed at the bottom of the first flip-chip 10 and the bottom of the second flip-chip 20 are arranged in different polar directions at the electrical connection surface between the first flip-chip 10 and the second flip-chip 20, and the bottoms of the two laminate flip-chips 70a, 70b are electrically coupled to the lower guide plate 30. Similarly, if a plurality of laminate flip-chips 70a, 70b are vertically and downwardly stacked, then the vertically stacked laminate flip-chip 70a, 70b are in different polar directions at their adjacent electrical connection surfaces, and the two bottom-layer laminate flip-chips 70a, 70b are electrically coupled to the lower guide plate 30.

Therefore, an electrical transmission path sequentially passing from the first electrode 50 through the first flip-chip 10, the one or more laminate flip-chips 70a, the lower guide plate 30, the one or more laminate flip-chips 70b, and the second flip-chip 20 to the second electrode 60 forms a series circuit.

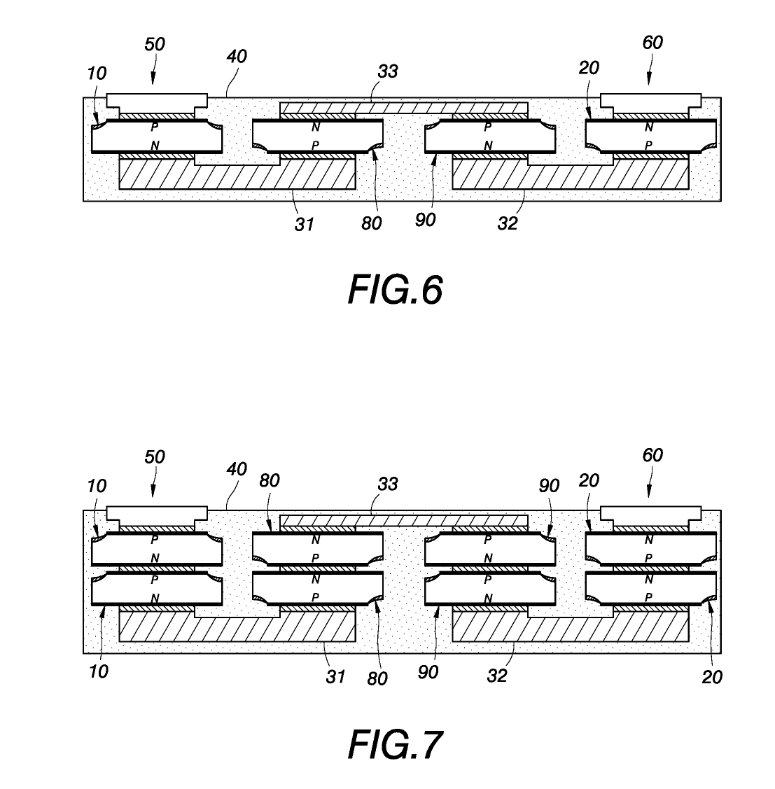

In a preferred embodiment of the unidirectional flip-chip as shown in FIG. 6, another way of increasing the quantity of the flip-chips is to add a third flip-chip 80 and a fourth flip-chip 90 horizontally arranged in parallel to each other on the first flip-chip 10 and the second flip-chip 20, and the lower guide plate 30 is cut and separated into a first lower guide plate 31 and a second lower guide plate 32, and the figure shows one third flip-chip 80 and one fourth flip-chip 90 as an example.

Wherein, the third flip-chip 80 and the first flip-chip 10 are arranged in different polar directions with respect to each other, and the bottom of the third flip-chip 80 and the bottom of the first flip-chip 10 are electrically coupled to the first lower guide plate 31; the fourth flip-chip 90 and the second flip-chip 20 are arranged in different polar directions with respect to each other, and the bottom of the fourth flip-chip 90 and the bottom of the second flip-chip 20 are electrically coupled to the second lower guide plate 32; and the third flip-chip 80 and the fourth flip-chip 90 are arranged in different polar directions with respect to each other, and an upper guide plate 33 is bridged between the top of the third flip-chip 80 and the top of the fourth flip-chip 90.

By the aforementioned electrical connection, an electrical transmission path sequentially passing from the first electrode 50 through the first flip-chip 10, the first lower guide plate 31, the third flip-chip 80, the upper guide plate 33, the fourth flip-chip 90, the second lower guide plate 32, and the second flip-chip 20 to the second electrode 60 forms a series circuit, so as to achieve the effect of increasing the quantity of flip-chips. Similarly, a fifth flip-chip and a sixth flip-chip may be arranged horizontally with an interval apart from each other, and a third lower guide plate and a second upper guide plate (not shown in the figure) may be added. As long as the increased number of the flip-chips is even, and the electrical transmission path forms a series circuit, such design can be implemented.

In FIG. 7, the first flip-chip 10, the second flip-chip 20, the third flip-chip 80 and the fourth flip-chip 90 may come with plural quantity and these flip-chips may be stacked vertically, and FIG. 7 shows that there are two laminate flip-chips each. In addition, the plurality of laminate first flip-chips 10, second flip-chips 20, third flip-chips 80 and fourth flip-chips 90 are arranged in different polar directions at their adjacent electrical connection surfaces. The difference between the preferred embodiment as shown in FIG. 6 and this preferred embodiment resides on that the first lower guide plate 31 of this preferred embodiment is electrically coupled to the bottom-layer third flip-chip 80 and the bottom of the bottom-layer first flip-chip 10; the second lower guide plate 32 is electrically coupled to the bottom of the bottom-layer fourth flip-chip 90 and the bottom of the bottom-layer second flip-chip 20, and the upper guide plate 33 is bridged between the top of the top-layer third flip-chip 80 and the top of the top-layer fourth flip-chip 90.

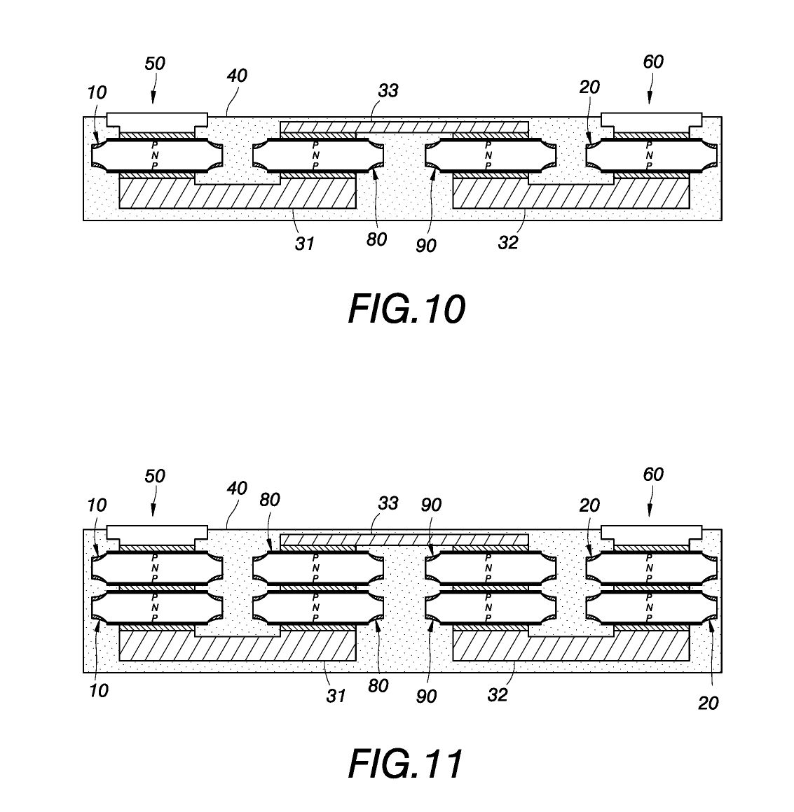

With reference to FIGS. 8 to 11 for all flip-chips which are bidirectionally conducted bidirectional flip-chips, the difference between this preferred embodiment and the preferred embodiment as shown in FIGS. 4 to 7 resides on that the bidirectional flip-chips of this embodiment form a series circuit, so that the flip-chips are electrically coupled in the same polar direction. For example, FIGS. 8 and 4 are compared, and FIG. 8 shows that the bottom of the first flip-chip 10 and the bottom of the second flip-chip 20 are arranged in the same polar direction. FIGS. 9 and 5 are compared, and FIG. 9 shows that the electrical connection surfaces of the first flip-chip 10, the second flip-chip 20 and the one or more laminate flip-chips 70a, 70b, are arranged in the same polar direction. FIGS. 10 and 11 are compared, and FIG. 11 shows that the one or more third flip-chips 80 and fourth flip-chips 90 are also arranged in the same polar direction.

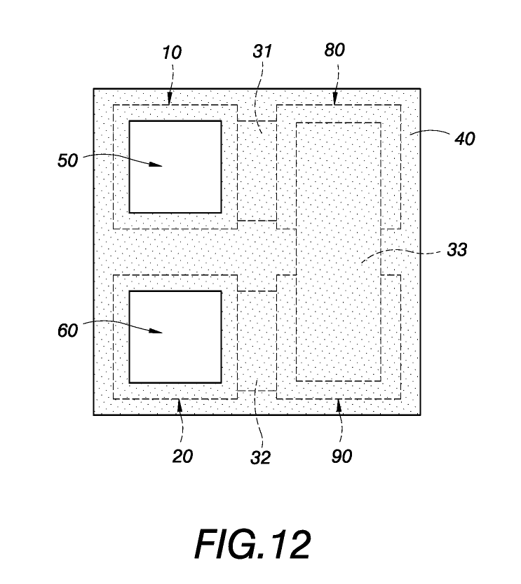

In FIG. 12, the first flip-chip 10 and the second flip-chip 20 have a third flip-chip 80 and a fourth flip-chip 90 horizontally arranged in parallel to each other, and they may arranged in matrix, as long as the flip-chips form a series circuit. Similarly, a fifth flip-chip and a sixth flip-chip, or more flip-chips in even number may be added.

While the invention has been described by means of specific embodiments, numerous modifications and variations could be made thereto by those skilled in the art without departing from the scope and spirit of the invention set forth in the claims.

What is claimed is:

1. (canceled)

2. (canceled)

3. A flip-chip packaging diode with a multichip structure, comprising:
at least one first flip-chip and at least one second flip-chip spaced from one another and horizontally disposed on a top surface of a lower guide plate, wherein a bottom of the first flip-chip and a bottom of the second flip-chip are electrically coupled to each other via the lower guide plate, and each of a top of the first flip-chip and a top of the second flip-chip has a conductive layer;
an insulating material disposed between the first flip-chip and the second flip-chip and an outer periphery of the first flip-chip and an outer periphery of the second flip-chip, so that the conductive layers at the top of the first flip-chip and the top of the second flip-chip are electrically separated from each other; and
a tin platform or a metal layer disposed on the conductive layers at the top of the first flip-chip and the top of the second flip-chip and exposed from the insulating material to serve as a first electrode and a second electrode respectively for electrically coupling to an external circuit;
wherein:
each of the bottom of the first flip-chip and the bottom of the second flip-chip comprises a laminate flip-chip, or a plurality of laminate flip-chips, wherein two laminate flip-chips, one respectively at the bottom of the first flip-chip and one at the bottom of the second flip-chip, are electrically coupled to the lower guide plate; and
the multichip structure defines a first serial electrical transmission path sequentially passing from the first electrode through the first flip-chip, the one or more laminate flip-chips at the bottom of the first flip ship, the lower guide plate, the one or more laminate flip-chips at the bottom of the second flip chip, and the second flip-chip to the second electrode.

4. A flip-chip packaging diode with a multichip structure, comprising:
at least one first flip-chip and at least one second flip-chip spaced from one another and horizontally disposed on a top surface of a lower guide plate, wherein a bottom of the first flip-chip and a bottom of the second flip-chip are electrically coupled to each other via the lower guide plate, and each of a top of the first flip-chip and a top of the second flip-chip has a conductive layer;
an insulating material disposed between the first flip-chip and the second flip-chip and an outer periphery of the first flip-chip and an outer periphery of the second flip-chip, so that the conductive layers at the top of the first flip-chip and the top of the second flip-chip are electrically separated from each other; and
a tin platform or a metal layer disposed on the conductive layers at the top of the first flip-chip and the top of the second flip-chip and exposed from the insulating material to serve as a first electrode and a second electrode respectively for electrically coupling to an external circuit;
wherein:
the first flip-chip and the second flip-chip are unidirectionally conducted unidirectional flip-chips, and the bottom of the first flip-chip and the bottom of the second flip-chip are arranged in different polar directions;
the at least one first flip-chip further comprises a third flip-chip, and the at least one second flip-chip further comprises a fourth flip-chip, the third flip-chip horizontally spaced from the first flip chip, the fourth flip-chip horizontally spaced from the second flip-chip, and the lower guide plate is electrically separated into a first lower guide plate and a second lower guide plate;
the third flip-chip and the first flip-chip are arranged in different polar directions with respect to each other, and a bottom of the third flip-chip and the bottom of the first flip-chip are electrically coupled to the first lower guide plate;
the fourth flip-chip and the second flip-chip are arranged in different polar directions with respect to each other, and a bottom of the fourth flip-chip and the bottom of the second flip-chip bottom are electrically coupled to the second lower guide plate;
the third flip-chip and the fourth flip-chip are arranged in different polar directions with respect to each other, and an upper guide plate electrically connects a top of the third flip-chip and a top of the fourth flip-chip; and
the multichip structure defines a serial electrical transmission path sequentially passing from the first electrode through the first flip-chip, the first lower guide plate, the third flip-chip, the upper guide plate, the fourth flip-chip, the second lower guide plate, and the second flip-chip to the second electrode.

5. (canceled)

6. (canceled)

7. The flip-chip packaging diode with a multichip structure according to claim 3, wherein the first flip-chip and the second flip-chip are bidirectionally conducted bidirectional flip-chips, and the first flip-chip and the second flip-chip are arranged in the same polar direction;
the plurality of laminate flip-chips are arranged in the same polar direction; and
the multichip structure further defines a second serial electrical transmission path opposite the first serial electrical transmission path.

8. A flip-chip packaging diode with a multichip structure, comprising:
at least one first flip-chip and at least one second flip-chip spaced from one another and horizontally disposed on a top surface of a lower guide plate, wherein a bottom of the first flip-chip and a bottom of the second flip-chip are electrically coupled to each other via the lower guide plate, and each of a top of the first flip-chip and a top of the second flip-chip has a conductive layer;
an insulating material disposed between the first flip-chip and the second flip-chip and an outer periphery of the first flip-chip and an outer periphery of the second flip-chip, so that the conductive layers at the top of the first flip-chip and the top of the second flip-chip are electrically separated from each other; and
a tin platform or a metal layer disposed on the conductive layers at the top of the first flip-chip and the top of the second flip-chip and exposed from the insulating material to serve as a first electrode and a second electrode respectively for electrically coupling to an external circuit;
wherein:
the first flip-chip and the second flip-chip are bidirectionally conducted bidirectional flip-chips, and the bottom of the first flip-chip and the bottom of the second flip-chip are arranged in the same polar direction;
the at least one first flip-chip further comprises a third flip-chip, and the at least one second flip-chip further comprises a fourth flip-chip, the first and third flip-chips arranged in spaced parallel relationship with each other, the second and fourth flip-chips arranged in spaced parallel relationship with each other, and the lower guide plate is electrically separated into a first lower guide plate and a second lower guide plate;
the third flip-chip and the first flip-chip are arranged in the same polar direction, and a bottom of the third flip-chip and the bottom of the first flip-chip are electrically coupled to the first lower guide plate;
the fourth flip-chip and the second flip-chip are arranged in the same polar direction, and a bottom of the fourth flip-chip and the bottom of the second flip-chip are electrically coupled to the second lower guide plate;
the third flip-chip and the fourth flip-chip are arranged in the same polar direction, and an upper guide plate electrically connects a top of the third flip-chip and a top of the fourth flip-chip; and
the multichip structure defines a serial electrical transmission path sequentially passes from the first electrode through the first flip-chip, the first lower guide plate, the third flip-chip, the upper guide plate, the fourth flip-chip, the second lower guide plate, and the second flip-chip to the second electrode, and an opposite electrical transmission path in the reverse direction also forms a series circuit.

9. The flip-chip packaging diode with a multichip structure according to claim 8, wherein the first flip-chip, the second flip-chip, the third flip-chip and the fourth flip-chip each comprises a plurality of vertically stacked flip-chips, and the plurality of vertically stacked first flip-chips, second flip-chips, third flip-chips and fourth flip-chips are arranged in the same polar direction;
wherein:
the first lower guide plate is electrically coupled to a respective bottom-layer flip-chip of the plurality of vertically stacked first flip-chips and the plurality of vertically stacked third flip-chips;
the second lower guide plate is electrically coupled to a respective bottom-layer flip-chip of the plurality of vertically stacked second flip-chips and the plurality of vertically stacked fourth flip-chips; and
the upper guide plate is electrically connected to a top of a top-layer flip-chip in the plurality of vertically stacked third flip-chips and a top of a top-layer flip-chip in the plurality of vertically stacked fourth flip-chips.

10. The flip-chip packaging diode with a multichip structure according to claim 3, wherein the first flip-chip and the second flip-chip are unidirectionally conducted unidirectional flip-chips, and the bottom of the first flip-chip and the bottom of the second flip-chip are arranged with different polar directions; and
the plurality of laminate flip-chips of the bottom of the first flip-chip and of the bottom of the second flip-chip are arranged in alternating polar directions; and
the two laminate flip-chips at the bottom of the first flip-chip and at the bottom of the second flip-chip have opposite polar directions.
